(19) United States
(12) Patent Application Publication
(10) Pub. No.: US 2026/0006997 A1
(43) Pub. Date: Jan. 1, 2026

(54) DISPLAY DEVICE AND ELECTRONIC DEVICE INCLUDING THE SAME

(71) Applicant: Samsung Display Co., Ltd., Yongin-si (KR)

(72) Inventors: Tae Hoon KIM, Yongin-si (KR); Won Kyu KWAK, Yongin-si (KR); Chang Kyu JIN, Yongin-si (KR); Hwan Soo JANG, Yongin-si (KR)

(21) Appl. No.: 19/085,959

(22) Filed: Mar. 20, 2025

(30) Foreign Application Priority Data
Jun. 26, 2024 (KR) 10-2024-0083714
Aug. 1, 2024 (KR) 10-2024-0102634

(51) Int. Cl. H10K 59/122; H10K 59/121; H10K 59/126; H10K 59/80

(52) U.S. Cl. CPC H10K 59/122; H10K 59/1213; H10K 59/126; H10K 59/8792; H10K 59/1216

(57) ABSTRACT

A display device includes: a substrate comprising emission areas; a circuit layer on the substrate; and an element layer on the circuit layer and comprising light emitting elements in the emission areas, wherein the circuit layer comprises light emitting pixel drivers electrically connected to the light emitting elements, each of the light emitting pixel drivers comprises a first transistor electrically connected between a first node and a second node, the element layer comprises: anode electrodes in the emission areas on the circuit layer; and a pixel defining layer on the circuit layer and containing a light absorbing material configured to absorb light, and the pixel defining layer comprises: anode openings overlapping the anode electrodes; and a light transmitting opening overlapping a part of the first transistor.

### CROSS-REFERENCE TO RELATED APPLICATION

The present application claims priority to and the benefit of Korean Patent Application No. 10-2024-0083714, filed on Jun. 26, 2024, in the Korean Intellectual Property Office, and Korean Patent Application No. 10-2024-0102634, filed on Aug. 1, 2024, in the Korean Intellectual Property Office, the entire disclosures of each of which are incorporated herein by reference.

### BACKGROUND

### 1. Field

Aspects of some embodiments of the present disclosure relate to a display device and an electronic device including the same.

### 2. Description of the Related Art

With the advance of information-oriented society, there is increasing consumer demand for display devices for displaying images in various ways. For example, display devices may be employed in various electronic devices such as smartphones, digital cameras, laptop computers, navigation devices, and smart televisions.

A display device may be, for example, a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

Organic light emitting display devices display images using light emitting elements, each including a light emitting layer made of an organic light emitting material. As described above, organic light emitting display devices implement image display using a self-light emitting element, and thus may have relatively superior performance in power consumption, response speed, luminous efficiency, luminance, and wide viewing angle compared to other display devices.

One surface of a display device may be a display surface including a display area at which images are displayed and a non-display area that is located at a periphery of the display area. Emission areas emitting light with respective luminances and colors may be arranged in the display area.

The above information disclosed in this Background section is only for enhancement of understanding of the background and therefore the information discussed in this Background section does not necessarily constitute prior art.

### SUMMARY

According to some embodiments, a display device may include light emitting elements located in emission areas and light emitting pixel drivers transmitting a driving current to the light emitting elements.

According to some embodiments, each of the light emitting pixel drivers may include a first transistor that generates the driving current.

According to some embodiments, when the first transistor is turned on according to the voltage difference between the gate electrode of the first transistor and the first electrode of the first transistor, a source-drain current of the first transistor may be generated. In addition, the source-drain current of the first transistor may be transmitted as the driving current for driving the light emitting element.

Because the light emitting element emits light according to the driving current, the current characteristics of the first transistor may affect the display quality of the display device.

Aspects of some embodiments of present disclosure include a display device that may be capable of relatively improving display quality by enhancing current characteristics of a first transistor, and an electronic device including the same.

However, aspects of embodiments according to the present disclosure are not restricted those specifically set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, there is provided a display device comprises a substrate comprising emission areas; a circuit layer on the substrate; and an element layer on the circuit layer and comprising light emitting elements in the emission areas. According to some embodiments, the circuit layer comprises light emitting pixel drivers electrically connected to the light emitting elements. According to some embodiments, each of the light emitting pixel drivers comprises a first transistor electrically connected between a first node and a second node. According to some embodiments, the element layer comprises anode electrodes in the emission areas on the circuit layer; and a pixel defining layer on the circuit layer and containing a light absorbing material absorbing light. According to some embodiments, the pixel defining layer comprises anode openings overlapping the anode electrodes; and a light transmitting opening overlapping a part of the first transistor.

According to some embodiments, the pixel defining layer covers edges of the anode electrodes. According to some embodiments, the light transmitting opening is spaced apart from the anode openings and the anode electrodes. According to some embodiments, the element layer further comprises light emitting layers on the anode electrodes through the anode openings; and a cathode electrode on the pixel defining layer and the light emitting layers. According to some embodiments, each of the light emitting elements has a structure in which the light emitting layer is interposed between the anode electrode and the cathode electrode facing each other.

According to some embodiments, the light emitting pixel drivers further comprise a second transistor electrically connected between a data line transmitting a data signal and the first node. According to some embodiments, the circuit layer comprises a light blocking layer on the substrate; a buffer layer covering the light blocking layer; a first semiconductor layer on the buffer layer; a first gate insulating layer covering the first semiconductor layer; a first gate conductive layer on the first gate insulating layer; a second gate insulating layer covering the first gate conductive layer; a second gate conductive layer on the second gate insulating layer; and a first interlayer insulating layer covering the second gate conductive layer. According to some embodiments, a channel portion, a first electrode portion and a second electrode portion of each of the first transistor and the second transistor are in the first semiconductor layer. According to some embodiments, a gate electrode of each of the first transistor and the second transistor is in the first gate conductive layer.

According to some embodiments, in the first semiconductor layer, the channel portion of the first transistor overlaps the gate electrode of the first transistor. According to some embodiments, in the first semiconductor layer, the first electrode portion of the first transistor is connected to one side of the channel portion of the first transistor and the second electrode portion of the second transistor. According to some embodiments, in the first semiconductor layer, the second electrode portion of the first transistor is connected to the other side of the channel portion of the first transistor. According to some embodiments, the light transmitting opening overlaps at least a part of the first electrode portion of the first transistor in the first semiconductor layer.

According to some embodiments, the light transmitting opening is adjacent to the gate electrode and the channel portion of the first transistor.

According to some embodiments, a part of the light blocking layer, which overlaps the gate electrode of the first transistor, is spaced apart from the light transmitting opening.

According to some embodiments, in a direction in which the gate electrode of the first transistor and the light transmitting opening face each other, a width of a part of the light blocking layer is less than a width of the gate electrode of the first transistor.

According to some embodiments, the gate electrode of the first transistor is electrically connected to the third node. According to some embodiments, the light emitting elements are electrically connected to the fourth node of the light emitting pixel drivers. According to some embodiments, the light emitting pixel drivers further comprise a pixel capacitor electrically connected between a first power line transmitting a first power source and the third node; a third transistor electrically connected between the second node and the third node; a fourth transistor electrically connected between a gate initialization voltage line transmitting a gate initialization voltage and the third node; a fifth transistor electrically connected between the first power line and the first node; a sixth transistor electrically connected between the second node and the fourth node; a seventh transistor electrically connected between an anode initialization voltage line transmitting an anode initialization voltage and the fourth node; and an eighth transistor electrically connected between a bias voltage line transmitting a bias voltage and the first node. According to some embodiments, a channel portion, a first electrode portion and a second electrode portion of each of the fifth transistor, the sixth transistor, the seventh transistor, and the eighth transistor are in the first semiconductor layer. According to some embodiments, a gate electrode of each of the fifth transistor, the sixth transistor, the seventh transistor, and the eighth transistor is in the first gate conductive layer.

According to some embodiments, the circuit layer further comprises a capacitor electrode in the second gate conductive layer and overlapping the gate electrode of the first transistor. According to some embodiments, the pixel capacitor is provided by a region where the capacitor electrode and the gate electrode of the first transistor overlap each other. According to some embodiments, the light transmitting opening is spaced apart from the capacitor electrode.

According to some embodiments, in a direction in which the gate electrode of the first transistor and the light emitting opening face each other, a width of the capacitor electrode is less than a width of the gate electrode of the first transistor.

According to some embodiments, the circuit layer further comprises a second semiconductor layer on the first interlayer insulating layer; a third gate insulating layer covering the second semiconductor layer; a third gate conductive layer on the third gate insulating layer; a second interlayer insulating layer covering the third gate conductive layer; a first source-drain conductive layer on the second interlayer insulating layer; a first planarization layer covering the first source-drain conductive layer; a second source-drain conductive layer on the first planarization layer; and a second planarization layer covering the second source-drain conductive layer. According to some embodiments, a channel portion, a first electrode portion and a second electrode portion of each of the third transistor and the fourth transistor are in the second semiconductor layer. According to some embodiments, a gate electrode of each of the third transistor and the fourth transistor is in the third gate conductive layer. According to some embodiments, an additional gate electrode of each of the third transistor and the fourth transistor is in the second gate conductive layer. At least a part of the first electrode portion of the first transistor in the first semiconductor layer overlaps the light transmitting opening, and is spaced apart from the third gate conductive layer, the first source-drain conductive layer, and the second source-drain conductive layer.

According to an aspect of the present disclosure, there is provided an electronic device comprises a display device providing a screen. The display device comprises a substrate comprising emission areas; a circuit layer on the substrate; and an element layer on the circuit layer and comprising light emitting elements in the emission areas. According to some embodiments, the circuit layer comprises light emitting pixel drivers electrically connected to the light emitting elements. According to some embodiments, each of the light emitting pixel drivers comprises a first transistor electrically connected between a first node and a second node. According to some embodiments, the element layer comprises anode electrodes in the emission areas on the circuit layer; and a pixel defining layer on the circuit layer and containing a light absorbing material absorbing light. According to some embodiments, the pixel defining layer comprises anode openings overlapping the anode electrodes; and a light transmitting opening overlapping a part of the first transistor.

According to some embodiments, the pixel defining layer covers edges of the anode electrodes. According to some embodiments, the light transmitting opening is spaced apart from the anode openings and the anode electrodes. According to some embodiments, the element layer further comprises light emitting layers on the anode electrodes through the anode openings; and a cathode electrode on the pixel defining layer and the light emitting layers. According to some embodiments, each of the light emitting elements has a structure in which the light emitting layer is interposed between the anode electrode and the cathode electrode facing each other.

According to some embodiments, the circuit layer comprises a light blocking layer on the substrate; a buffer layer covering the light blocking layer; a first semiconductor layer on the buffer layer; a first gate insulating layer covering the first semiconductor layer; a first gate conductive layer on the first gate insulating layer; a second gate insulating layer covering the first gate conductive layer; a second gate conductive layer on the second gate insulating layer; and a first interlayer insulating layer covering the second gate conductive layer. According to some embodiments, a second semiconductor layer on the first interlayer insulating layer; a third gate insulating layer covering the second semiconductor layer; a third gate conductive layer on the third gate insulating layer; a second interlayer insulating layer covering the third gate conductive layer; a first source-drain conductive layer on the second interlayer insulating layer; a first planarization layer covering the first source-drain conductive layer; a second source-drain conductive layer on the first planarization layer; and a second planarization layer covering the second source-drain conductive layer. According to some embodiments, a channel portion, a first electrode portion and a second electrode portion of each of the first transistor and the second transistor are in the first semiconductor layer. According to some embodiments, a gate electrode of each of the first transistor and the second transistor is in the first gate conductive layer. According to some embodiments, in the first semiconductor layer, the channel portion of the first transistor overlaps the gate electrode of the first transistor. According to some embodiments, in the first semiconductor layer, the first electrode portion of the first transistor is connected to one side of the channel portion of the first transistor and the second electrode portion of the second transistor. According to some embodiments, in the first semiconductor layer, the second electrode portion of the first transistor is connected to the other side of the channel portion of the first transistor. According to some embodiments, the light transmitting opening overlaps at least a part of the first electrode portion of the first transistor in the first semiconductor layer.

According to some embodiments, at least a part of the first electrode portion of the first transistor in the first semiconductor layer overlaps the light transmitting opening, and is spaced apart from the third gate conductive layer, the first source-drain conductive layer, and the second source-drain conductive layer.

According to some embodiments, the light transmitting opening is adjacent to the gate electrode and the channel portion of the first transistor. According to some embodiments, a part of the light blocking layer, which overlaps the gate electrode of the first transistor, is spaced apart from the light transmitting opening.

According to some embodiments, in a direction in which the gate electrode of the first transistor and the light transmitting opening face each other, a width of a part of the light blocking layer is less than a width of the gate electrode of the first transistor.

According to some embodiments, the gate electrode of the first transistor is electrically connected to the third node. According to some embodiments, the light emitting elements are electrically connected to the fourth node of the light emitting pixel drivers. According to some embodiments, the light emitting pixel drivers further comprise a second transistor electrically connected between a data line transmitting a data signal and the first node; a pixel capacitor electrically connected between a first power line transmitting a first power source and the third node; a third transistor electrically connected between the second node and the third node; a fourth transistor electrically connected between a gate initialization voltage line transmitting a gate initialization voltage and the third node; a fifth transistor electrically connected between the first power line and the first node; a sixth transistor electrically connected between the second node and the fourth node; a seventh transistor electrically connected between an anode initialization voltage line transmitting an anode initialization voltage and the fourth node; and an eighth transistor electrically connected between a bias voltage line transmitting a bias voltage and the first node. According to some embodiments, a channel portion, a first electrode portion and a second electrode portion of each of the second transistor, the fifth transistor, the sixth transistor, the seventh transistor, and the eighth transistor are in the first semiconductor layer. According to some embodiments, a gate electrode of each of the second transistor, the fifth transistor, the sixth transistor, the seventh transistor, and the eighth transistor is in the first gate conductive layer. According to some embodiments, a channel portion, a first electrode portion and a second electrode portion of each of the third transistor and the fourth transistor are in the second semiconductor layer. According to some embodiments, a gate electrode of each of the third transistor and the fourth transistor is in the third gate conductive layer. According to some embodiments, an additional gate electrode of each of the third transistor and the fourth transistor is in the second gate conductive layer.

According to some embodiments, the circuit layer further comprises a capacitor electrode in the second gate conductive layer and overlapping the gate electrode of the first transistor. According to some embodiments, the pixel capacitor is provided by a region where the capacitor electrode and the gate electrode of the first transistor overlap each other. According to some embodiments, the light transmitting opening is spaced apart from the capacitor electrode.

According to some embodiments, in a direction in which the gate electrode of the first transistor and the light emitting opening face each other, a width of the capacitor electrode is less than a width of the gate electrode of the first transistor.

According to some embodiments, the display device includes a circuit layer on a substrate, and an element layer on the circuit layer.

According to some embodiments, the element layer may include light emitting elements in the emission areas.

According to some embodiments, the circuit layer may include light emitting pixel drivers that are electrically connected to the light emitting elements.

According to some embodiments, each of the light emitting pixel drivers may include a first transistor electrically connected between a first node and a second node.

According to some embodiments, the element layer may include anode electrodes in emission areas on the circuit layer, a pixel defining layer on the circuit layer and containing a light absorbing material absorbing light, anode openings formed in the pixel defining layer and overlapping the anode electrodes, and a light transmitting opening formed in the pixel defining layer and overlapping a part of the first transistor.

As such, according to some embodiments, as the pixel defining layer includes a light absorbing material, light leakage defects in a non-emission area between the emission areas may be reduced, and the luminance of each emission area may be enhanced and the color of each emission area may become clear. As a result, the display quality of the display device and the electronic device including the same may be relatively improved.

In addition, according to some embodiments, a part of the first transistor may be exposed to light incident through the light transmitting opening, so that the current characteristics of the first transistor may be relatively enhanced.

That is, according to some embodiments, the first transistor may include a channel portion, a first electrode portion connected to one side of the channel portion, a second electrode portion connected to the other side of the channel portion, and a gate electrode overlapping the channel portion. According to some embodiments, the channel portion, the first electrode portion, and the second electrode portion of the first transistor may be in a first semiconductor layer on a buffer layer. According to some embodiments, the gate electrode of the first transistor may be on a first gate conductive layer on a first gate insulating layer covering the first semiconductor layer.

According to some embodiments, the first electrode portion of the first transistor may be electrically connected to a data line through a turned-on second transistor.

According to some embodiments, the light transmitting opening may overlap at least a part of the first electrode portion of the first transistor. According to some embodiments, when light is incident on a semiconductor material of the first semiconductor layer, electrons and holes in the semiconductor material react to light energy to generate electron-hole pairs, thereby generating a photocurrent. Accordingly, the current characteristics of the first transistor may be relatively enhanced by the light incident through the light transmitting opening. As a result, the luminance of the light emitting element may be relatively enhanced, and thus the display quality of the display device and the electronic device including the same may be improved.

However, the characteristics of embodiments according to the present disclosure are not limited to those described above and various other characteristics are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating the display device of FIG. 1;

FIG. 3 is a cross-sectional view taken along the line A-A′ of FIG. 2;

FIG. 4 is a layout diagram illustrating part B of FIG. 2;

FIG. 5 is an equivalent circuit diagram showing the light emitting pixel driver of FIG. 4;

FIG. 6 is a plan view showing a light blocking layer, a first semiconductor layer, and a first gate conductive layer in part C of FIG. 4;

FIG. 7 is a plan view showing a second gate conductive layer in part C of FIG. 4;

FIG. 8 is a plan view showing a second semiconductor layer and a third gate conductive layer in part C of FIG. 4;

FIG. 9 is a plan view showing a first source-drain conductive layer of part C of FIG. 4;

FIG. 10 is a plan view showing a second source-drain conductive layer of part C of FIG. 4;

FIG. 11 is a plan view showing an anode electrode, an anode opening, and a light transmitting opening in part C of FIG. 4;

FIG. 12 is a plan view showing a light blocking layer, a first semiconductor layer, a first gate conductive layer, a second gate conductive layer, a first source-drain conductive layer, and the light transmitting opening in part C of FIG. 4; and

FIG. 13 is a cross-sectional view taken along the line D-D′ of FIG. 11.

### DETAILED DESCRIPTION

Aspects of some embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, further details according to some embodiments will be described with reference to the accompanying drawings.

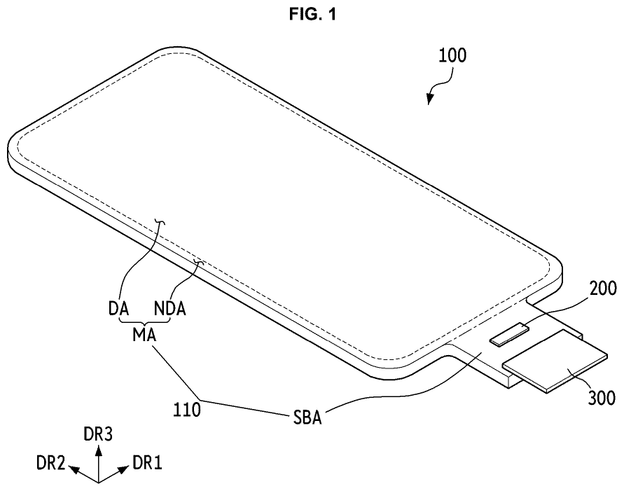

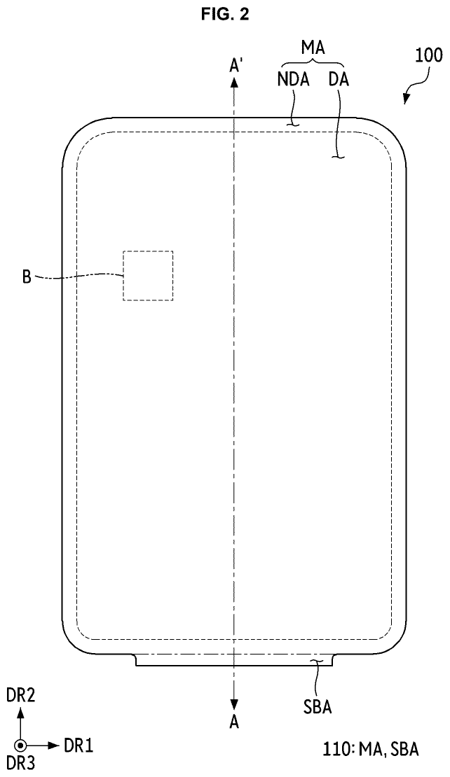

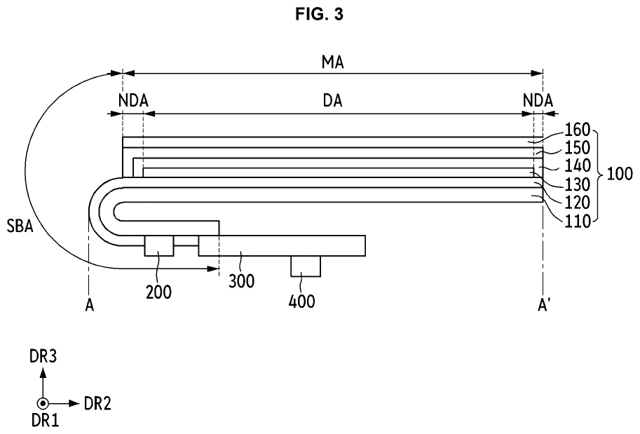

FIG. 1 is a perspective view illustrating a display device according to some embodiments. FIG. 2 is a plan view illustrating the display device of FIG. 1. FIG. 3 is a cross-sectional view taken along the line A-A′ of FIG. 2.

Referring to FIGS. 1 and 2, a display device 100 which is a device for displaying a moving image (e.g., video image) or a still image (e.g., a static image), may be used as a display screen of various electronic devices, such as a television, a laptop computer, a monitor, a billboard and an Internet-of-Things (IoT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). In the following description, it is assumed that the display device 100 is an organic light emitting display device. However, the present disclosure is not limited thereto, and may be applied to a display device including an organic insulating material, an organic light emitting material, and a metal material.

The display device 100 may be formed to be flat, but embodiments according to the present disclosure are not limited thereto. For example, the display device 100 may include a curved portion formed at left and right ends and having a constant curvature or a varying curvature. In addition, the display device 100 may be formed to be flexible so that it can be curved, bent, folded, or rolled.

As illustrated in FIGS. 1, 2 and 3, the display device 100 includes a substrate 110.

The substrate 110 may include a main region MA corresponding to a display surface of the display device 100 and a sub-region SBA protruding from one side of the main region MA.

As shown in FIG. 2, the main region MA may include a display area DA located at most of the center thereof, and a non-display area NDA arranged around (e.g., in a periphery or outside a footprint of) the display area DA.

The display area DA may, in a plan view, be formed in a rectangular shape having short sides in a first direction DR1 and long sides in a second direction DR2 crossing the first direction DR1. The corner where the short side in the first direction DR1 and the long side in the second direction DR2 meet may be, for example, rounded to have a curvature (e.g., a set or predetermined curvature) or may be right-angled. The planar shape of the display area DA is not limited to the rectangular shape, and may be formed in another polygonal shape, a circular shape or an elliptical shape.

The non-display area NDA may be located at the edge of the main region MA to surround (e.g., in a periphery or outside a footprint of) the display area DA.

The sub-region SBA may be a region extending in the second direction DR2 from a part of one side of the main region MA extending in the first direction DR1.

The sub-region SBA may include a bending area that is transformed into a bent shape.

FIGS. 2 and 3 illustrate the display device 100 with a part of the sub-region SBA in a bent state.

As shown in FIG. 3, the sub-region SBA may include the bending area that is transformed into a bent shape, a first sub-region located between one side of the main region MA and one side of the bending area, and a second sub-region extending from the other side of the bending area.

When the bending area is transformed into a bent shape, the second sub-region may be located on the rear surface of the display device 100 and may overlap the main region MA.

A display driving circuit 200 provided as an integrated circuit (IC) chip may be mounted in the second sub-region SB2.

A circuit board 300 may be bonded to one side of the second sub-region SB2.

A touch driving circuit 400 provided as an integrated circuit (IC) chip may be mounted on the circuit board 300.

Referring to FIG. 3, the display device 100 according to some embodiments includes the substrate 110, a circuit layer 120 located or mounted on the substrate 110, and an element layer 130 located or mounted on the circuit layer 120.

The display device 100 according to some embodiments may further include an encapsulation layer 140 located or mounted on the element layer 130, and a touch sensor layer 150 located or mounted on the encapsulation layer 140.

Also, the display device 100 according to some embodiments may further include a polarization layer 160 located on the touch sensor layer 150 to reduce reflection of external light.

The substrate 110 may be formed of an insulating material such as a polymer resin. For example, the substrate 110 may be formed of polyimide. The substrate 110 may be a flexible substrate which can be bent, folded, or rolled.

Alternatively, the substrate 110 may be formed of an insulating material such as glass or the like.

The substrate 110 may include the main region MA and the sub-region SBA. The main region MA may include the display area DA and the non-display area NDA surrounding (e.g., in a periphery or outside a footprint of) the display area DA.

The circuit layer 120 may include light emitting pixel drivers EPD that output a driving current.

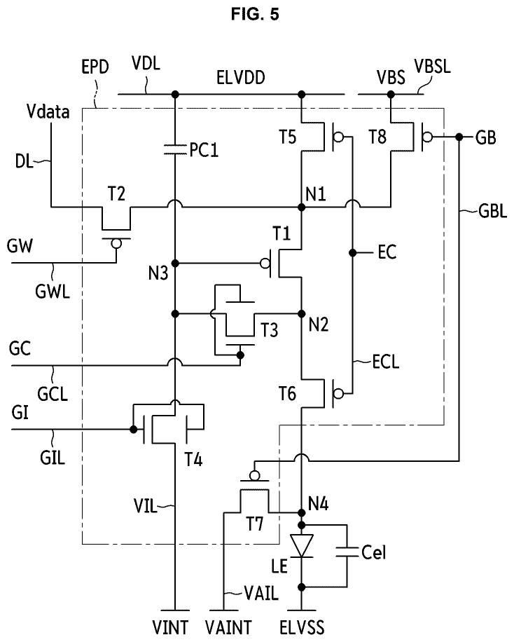

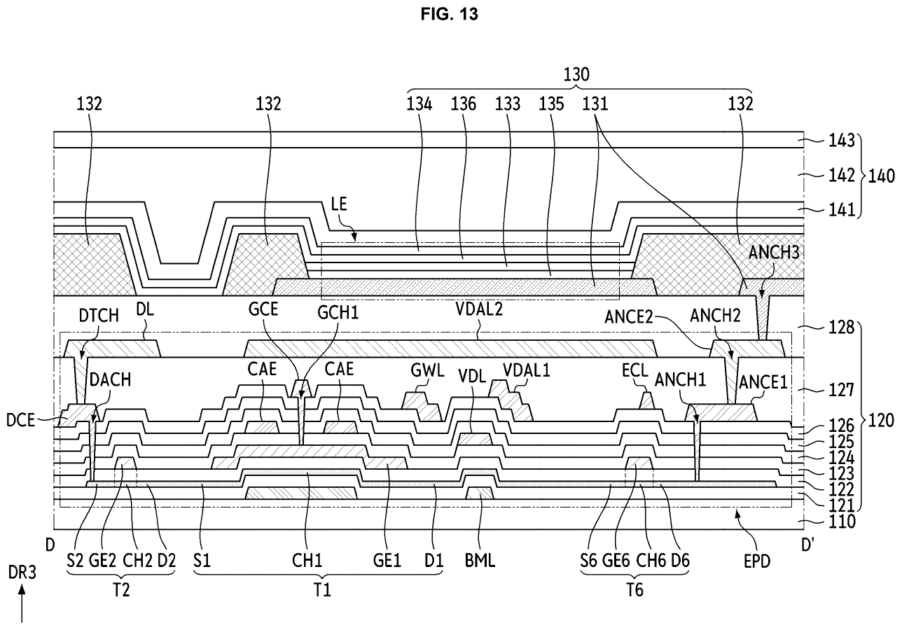

The element layer 130 may include light emitting elements LE (see FIGS. 5 and 13) that emit light based on the driving current.

The encapsulation layer 140 may have a structure in which at least one organic film is interposed between two or more inorganic films while covering the element layer 130. The element layer 130 may be encapsulated between the circuit layer 120 and the encapsulation layer 140.

The touch sensor layer 150 may include touch electrodes for detecting a signal that varies depending on the touch of a person or an object and sensing a point in the main region MA in which the touch of the person or the object has occurred.

The polarization layer 160 blocks external light reflected from the touch sensor layer 150, the encapsulation layer 140, the element layer 130, and the circuit layer 120, and the interfaces thereof, and this is to prevent or reduce the deterioration of visibility of an image due to external light reflection.

According to some embodiments, the display device 100 may further include the display driving circuit 200, provided as an integrated circuit (IC) chip and mounted on the sub-region SBA of the substrate 110.

The display driving circuit 200 may supply data signals Vdata (see FIG. 5) to data lines DL (see FIG. 5) of the circuit layer 120.

According to some embodiments, the display device 100 may further include the circuit board 300 bonded to the sub-region SBA of the substrate 110. The circuit board 300 may be bonded to pads located in the sub-region SBA of the substrate 110 by using a low-resistance, high-reliability material such as an anisotropic conductive film or SAP.

The touch driving circuit 400 may be mounted on the circuit board 300.

When the touch sensor layer 150 includes capacitive touch electrodes and sensing electrodes, the touch driving circuit 400 may detect a touch based on a change in capacitance. However, this is merely an example, and the touch sensor layer 150 and the touch driving circuit 400 of FIG. 3 may be provided with a touch detection method other than the capacitive method.

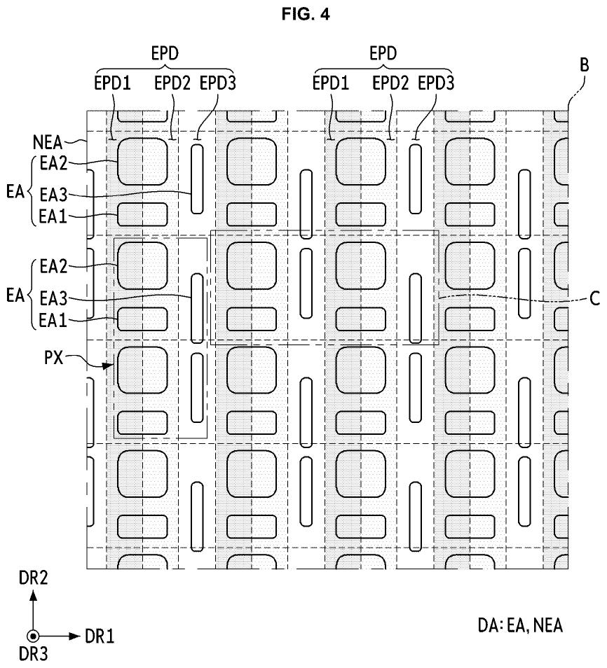

FIG. 4 is a layout diagram illustrating part B of FIG. 2.

Referring to FIG. 4, the display area DA of the display device 100 according to some embodiments may include emission areas EA. In addition, the display area DA may further include a non-emission area located in a gap between the emission areas EA.

The emission areas EA may have a rhombic shape or a rectangular shape in a plan view. However, this is only an example, and the planar shape of the emission areas EA according to some embodiments of the present disclosure is not limited to that illustrated in FIG. 4. That is, in a plan view, the emission areas EA may have a polygonal shape such as an irregular shape, a quadrangle, a pentagon, and a hexagon, or may have a circular or elliptical shape including the edge of a curve.

The emission areas EA may include a first emission area EA1 that emits light in a first wavelength band, a second emission area EA2 that emits light in a second wavelength band lower than the first wavelength band, and a third emission area EA3 that emits light in a third wavelength band lower than the second wavelength band.

For example, the first wavelength band may be in a range of 600 nanometers (nm) to 750 nm (or about 600 nm to about 750 nm), and the light in the first wavelength band may be red. The second wavelength band is in a range of 480 nm to 560 nm (or about 480 nm to about 560 nm), and light in the second wavelength band may be green. The third wavelength band is in a range of 370 nm to 460 nm (or about 370 nm to about 460 nm), and light in the third wavelength band may be blue.

According to some embodiments, the first emission areas EA1 and the second emission areas EA2 may be arranged alternately in the second direction DR2.

The third emission areas EA3 may be arranged parallel to each other in the second direction DR2.

The third emission areas EA3 may be located between the first emission areas EA1 or between the second emission areas EA2 in the first direction DR1.

The second emission areas EA2 may be adjacent to the first emission areas EA1 and the third emission areas EA3 in diagonal directions DR4 and DR5 crossing the first direction DR1 and the second direction DR2.

The pixels PX displaying respective luminances and colors may be provided by at least one first emission area EA1, at least one second emission area EA2, and at least one third emission area EA3 that are adjacent to each other, among these emission areas EA.

In other words, the pixel PX may be a basic unit for displaying various colors including white with a luminance (e.g., a set or predetermined luminance).

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

The element layer 130 (see FIG. 3) of the display device 100 may include the light emitting elements LE (see FIGS. 5 and 13) located in the emission areas EA.

The circuit layer 120 (see FIG. 3) of the display device 100 may include the light emitting pixel drivers EPD that are electrically connected to the light emitting elements LE.

The light emitting pixel drivers EPD may include first light emitting pixel drivers EPD1 electrically connected to the light emitting elements LE of the first emission areas EA1, second light emitting pixel drivers EPD2 electrically connected to the light emitting elements LE of the second emission areas EA2, and third light emitting pixel drivers EPD3 electrically connected to the light emitting elements LE of the third emission areas EA3.

The first light emitting pixel drivers EPD1 may be arranged side by side in the second direction DR2.

The second light emitting pixel drivers EPD2 may be arranged side by side in the second direction DR2.

The third light emitting pixel drivers EPD3 may be arranged side by side in the second direction DR2.

The first light emitting pixel drivers EPD1 may be arranged between the third light emitting pixel drivers EPD3 and the second light emitting pixel drivers EPD2 in the first direction DR1.

The second light emitting pixel drivers EPD2 may be arranged between the first light emitting pixel drivers EPD1 and the third light emitting pixel drivers EPD3 in the first direction DR1.

The third light emitting pixel drivers EPD3 may be arranged between the second light emitting pixel drivers EPD2 and the first light emitting pixel drivers EPD1 in the first direction DR1.

FIG. 5 is an equivalent circuit diagram showing the light emitting pixel driver of FIG. 4. Although FIG. 5 illustrates various components in a light emitting pixel driver according to some embodiments, embodiments according to the present disclosure are not limited thereto, and according to various embodiments, the light emitting pixel driver may include additional components or fewer components without departing from the spirit and scope of embodiments according to the present disclosure.

Referring to FIG. 5, one of the light emitting pixel drivers EPD may be electrically connected between a first power source ELVDD and one of the light emitting elements LE. One light emitting element LE may be electrically connected between one light emitting pixel driver EPD and a second power source ELVSS.

The second power source ELVSS may be at a voltage level lower than that of the first power source ELVDD.

That is, the anode electrode of the light emitting element LE is electrically connected to the light emitting pixel driver EPD, and the cathode electrode of the light emitting element LE may be applied with a voltage of the second power source ELVSS having a voltage level lower than the first power source ELVDD.

A capacitor Cel connected in parallel with the light emitting element LE refers to a parasitic capacitance between the anode electrode and the cathode electrode.

The circuit layer 120 (see FIG. 3) may include a data line DL transmitting a data signal Vdata, a first power line VDL transmitting the first power source ELVDD to the light emitting pixel drivers EPD, a gate initialization voltage line VIL transmitting a gate initialization voltage VINT, an anode initialization voltage line VAIL transmitting an anode initialization voltage VAINT, and a bias voltage line VBSL transmitting a bias voltage VBS.

The circuit layer 120 may further include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a bias control line GBL for transmitting a bias control signal GB.

One light emitting pixel driver EPD of the circuit layer 120 may include a first transistor T1 configured to generate a driving current for driving the light emitting element LE, two or more transistors T2 to T8 electrically connected to the first transistor T1, and at least one capacitor PC1.

The first transistor T1 may be electrically connected between a first node N1 and a second node N2. The first node N1 is electrically connected to the first electrode (e.g., source electrode) of the first transistor T1. The second node N2 is electrically connected to the second electrode (e.g., drain electrode) of the first transistor T1.

The pixel capacitor PC1 may be electrically connected between the first power line VDL and a third node N3. The third node N3 is electrically connected to the gate electrode of the first transistor T1.

The second transistor T2 may be electrically connected between the data line DL and the first node N1.

The second transistor T2 may be turned on by the scan write signal GW of the scan write line GWL.

The first electrode of the first transistor T1 may be electrically connected to the data line DL through the turned-on second transistor T2.

The fifth transistor T5 may be electrically connected between the first node N1 and the first power line VDL.

The sixth transistor T6 may be electrically connected between the second node N2 and a fourth node N4. The fourth node N4 is electrically connected to the anode electrode of the light emitting element LE.

The fifth transistor T5 and the sixth transistor T6 may be turned on by the emission control signal EC of the emission control line ECL.

The first electrode of the first transistor T1 may be electrically connected to the first power line VDL through the turned-on fifth transistor T5.

The second electrode of the first transistor T1 may be electrically connected to the anode electrode of the light emitting element LE through the turned-on sixth transistor T6.

The third node N3 is electrically connected to the gate electrode of the first transistor T1, and is electrically connected to the first power line VDL through the pixel capacitor PC1, so that the potential of the gate electrode of the first transistor T1 may be maintained at the voltage charged in the first power line VDL.

Accordingly, when the data signal Vdata of the data line DL is transmitted to the first node N1 through the turned-on second transistor T2, the voltage difference between the gate electrode of the first transistor T1 and the first electrode of the first transistor T1 may correspond to a difference voltage between the first power source ELVDD and the data signal Vdata.

In this case, when the voltage difference between the gate electrode of the first transistor T1 and the first electrode of the first transistor T1, i.e., the gate-source voltage difference becomes equal to or greater than a threshold voltage, the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light emitting element LE between the first power line VDL and a second power line VSL. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1.

The third transistor T3 may be turned on by the gate control signal GC of the gate control line GCL.

Through the turned-on third transistor T3, the voltage difference between the second node N2 and the third node N3 may be initialized.

The fourth transistor T4 may be electrically connected between the gate initialization voltage line VIL and the third node N3. That is, the fourth transistor T4 may be connected between the gate electrode of the first transistor T1 and the gate initialization voltage line VIL.

The fourth transistor T4 may be turned on by the scan initialization signal GI of the scan initialization line GIL.

Through the turned-on fourth transistor T4, the potential of the third node N3 may be initialized to a gate initialization voltage VINT.

The third transistor T3 and the fourth transistor T4 may be provided as N-type MOSFETs.

The seventh transistor T7 may be electrically connected between the fourth node N4 and the anode initialization voltage line VAIL. That is, the seventh transistor T7 may be electrically connected between the anode electrode of the light emitting element LE and the anode initialization voltage line VAIL.

The eighth transistor T8 may be electrically connected between the first node N1 and the bias voltage line VBSL. That is, the eighth transistor T8 may be electrically connected between the first electrode of the first transistor T1 and the bias voltage line VBSL.

The seventh transistor T7 and the eighth transistor T8 may be turned on by the bias control signal GB of the bias control line GBL.

Through the turned-on seventh transistor T7, the potential of the fourth node N4 may be initialized to the anode initialization voltage VAINT.

The potential of the first node N1 may be initialized to the bias voltage VBS through the turned-on eighth transistor T8.

According to some embodiments, the third transistor T3 and the fourth transistor T4 among the first to eighth transistors T1 to T8 included in the light emitting pixel driver EPD are provided as N-type MOSFETs, and the remaining transistors T1, T2, and T5 to T8 except for the third transistor T3 and the fourth transistor T4 may be provided as P-type MOSFETs.

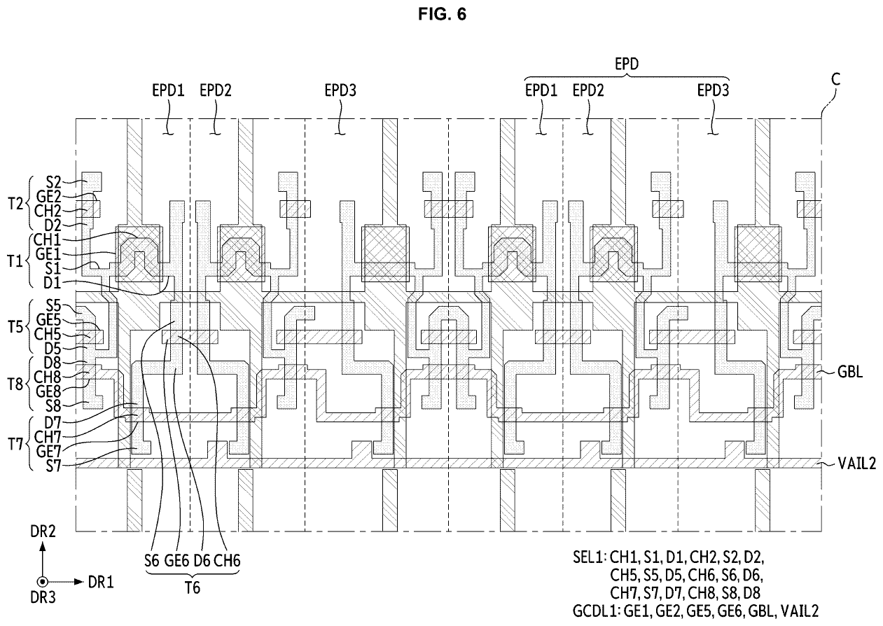

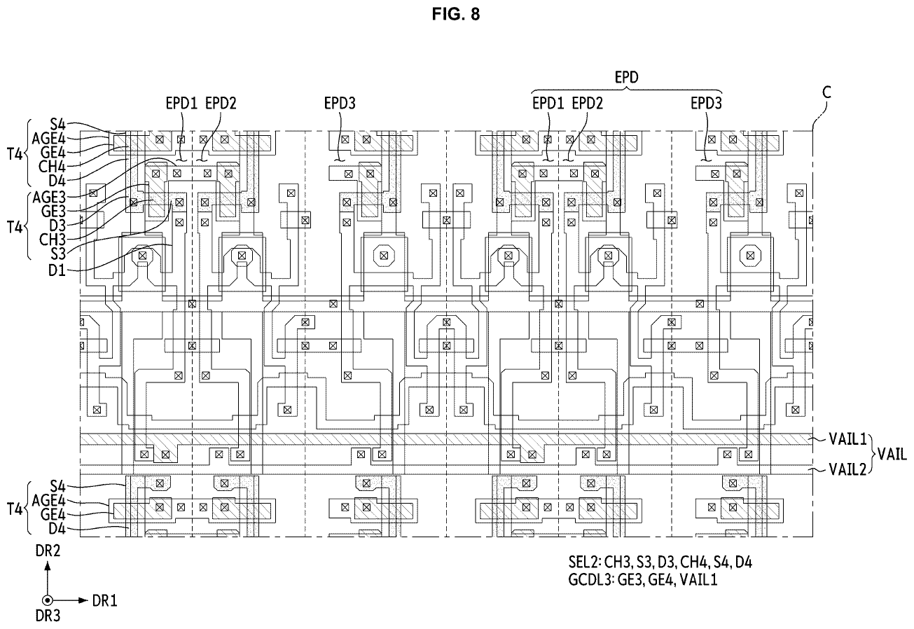

To this end, the circuit layer 120 may include a first semiconductor layer SEL1 (see FIG. 6) for providing the P-type MOSFETs and a second semiconductor layer SEL2 (see FIG. 8) for providing the N-type MOSFETs.

The first semiconductor layer SEL1 may include a channel portion, a first electrode portion, and a second electrode portion of each of the P-type MOSFETs T1, T2, T5, T6, T7, and T8 (see FIG. 5).

The second semiconductor layer SEL2 may include a channel portion, a first electrode portion, and a second electrode portion of each of the N-type MOSFETs T3 and T4 (see FIG. 5).

In each of the first to eighth transistors T1 to T8, the first electrode portion may be connected to one side of the channel portion, and the second electrode portion may be connected to the other side of the channel portion.

The first electrode portion may be a first electrode or a source electrode.

The second electrode portion may be a second electrode or a drain electrode.

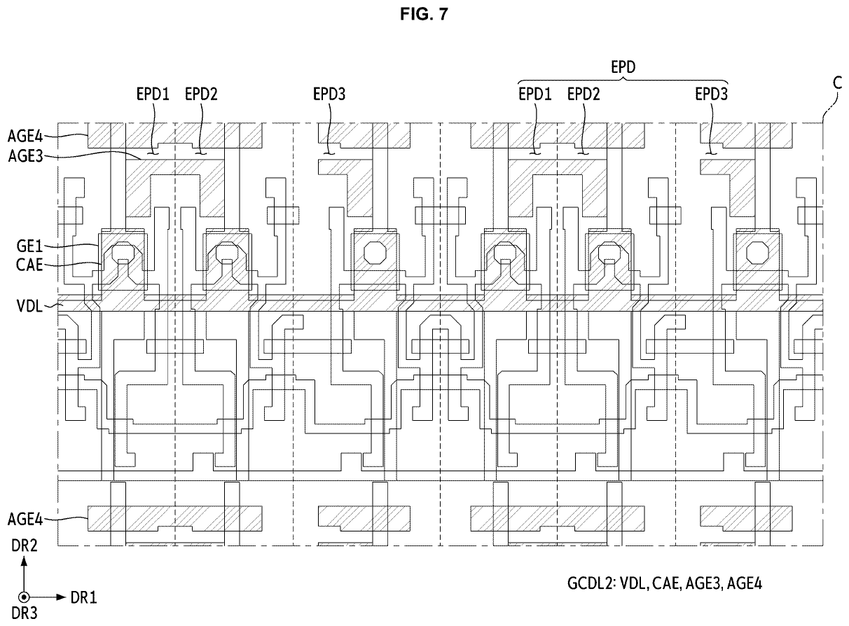

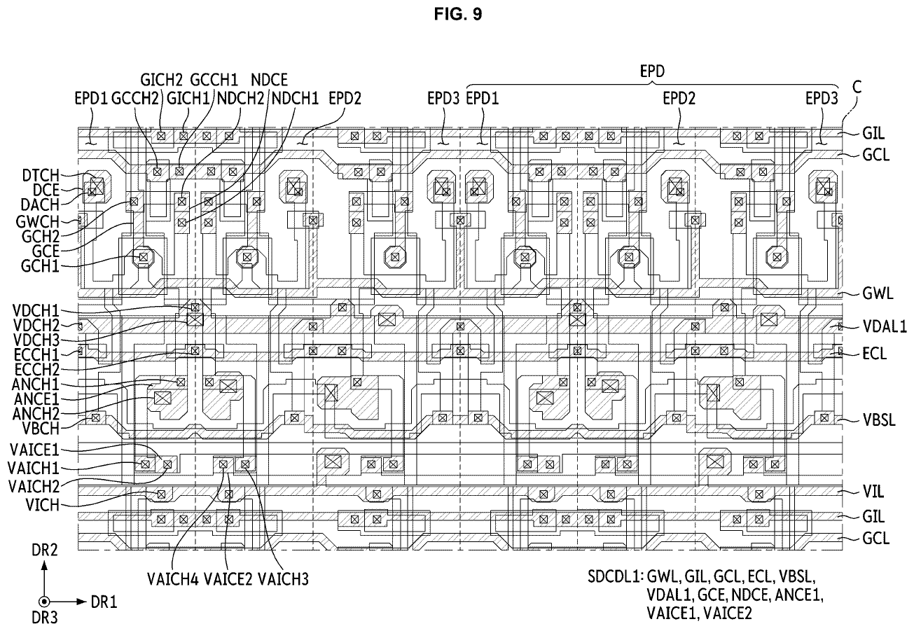

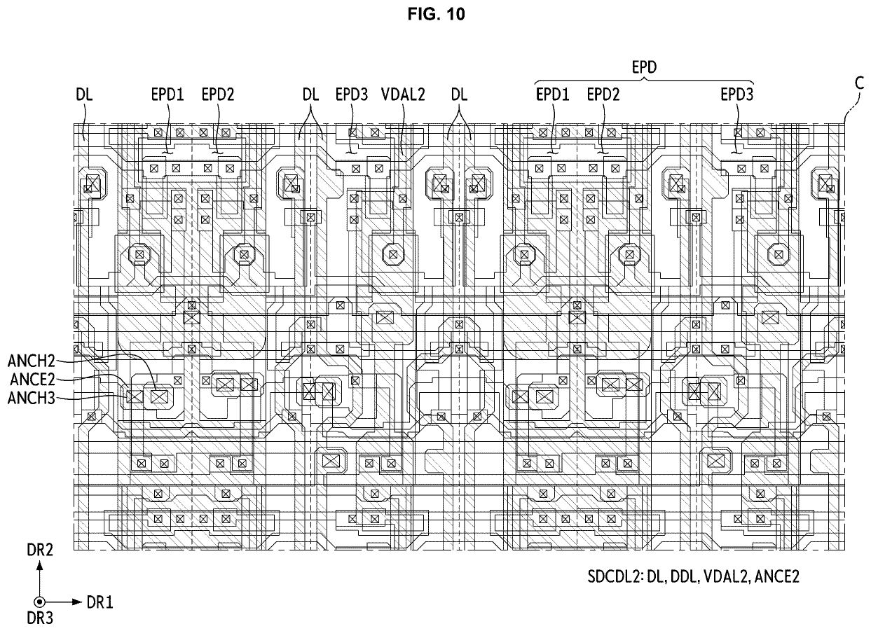

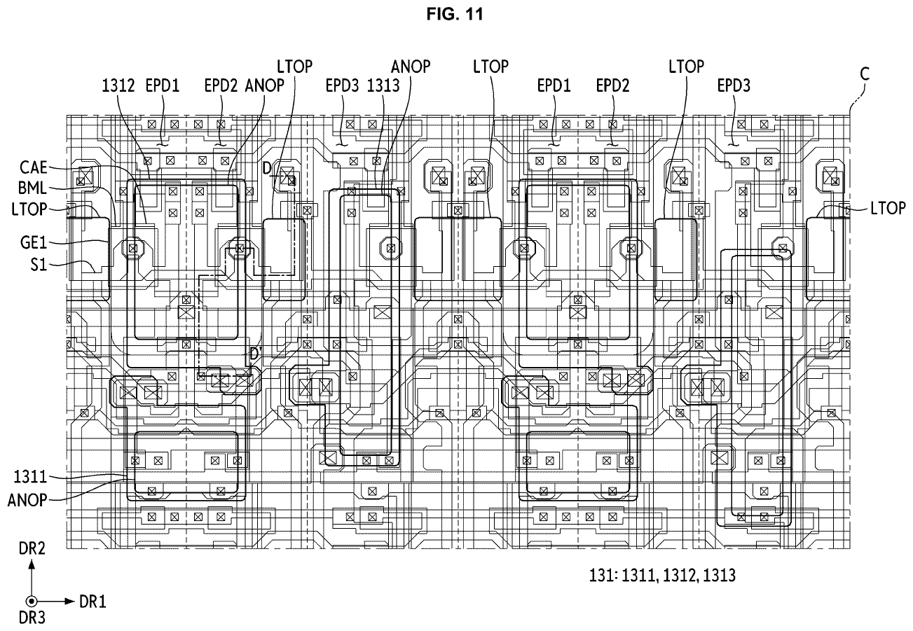

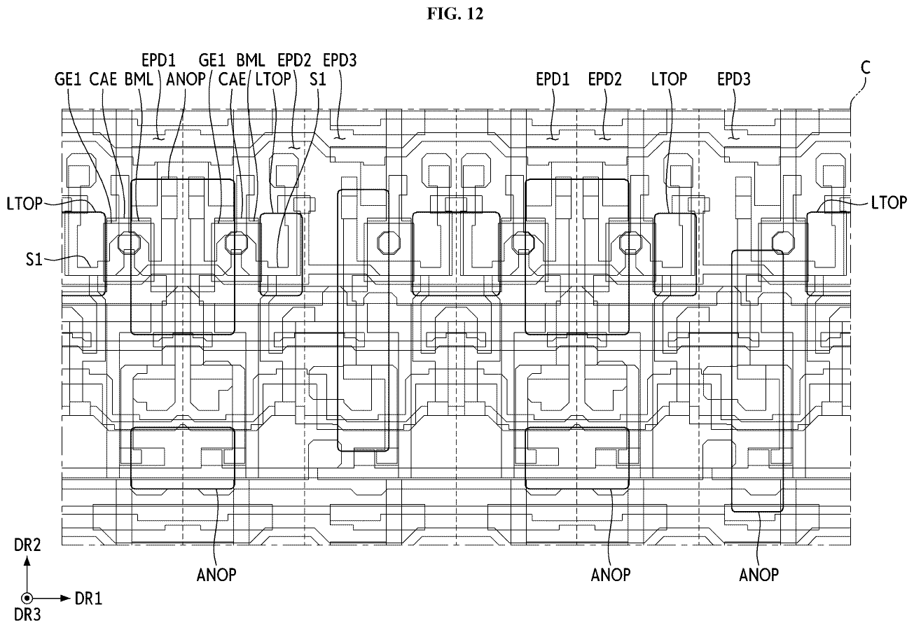

FIG. 6 is a plan view showing a light blocking layer, a first semiconductor layer, and a first gate conductive layer in part C of FIG. 4. FIG. 7 is a plan view showing a second gate conductive layer in part C of FIG. 4. FIG. 8 is a plan view showing a second semiconductor layer and a third gate conductive layer in part C of FIG. 4. FIG. 9 is a plan view showing a first source-drain conductive layer of part C of FIG. 4. FIG. 10 is a plan view showing a second source-drain conductive layer of part C of FIG. 4. FIG. 11 is a plan view showing an anode electrode, an anode opening, and a light transmitting opening in part C of FIG. 4. FIG. 12 is a plan view showing a light blocking layer, a first semiconductor layer, a first gate conductive layer, a second gate conductive layer, a first source-drain conductive layer, and the light transmitting opening in part C of FIG. 4. FIG. 13 is a cross-sectional view taken along the line D-D′ of FIG. 11.

First, as shown in FIG. 13, the display device 100 according to some embodiments may include a circuit layer 120 located on the substrate 110, and an element layer 130 located on the circuit layer 120.

The circuit layer 120 may include a light blocking layer BML located on the substrate 110, a buffer layer 121 covering the light blocking layer BML, the first semiconductor layer SEL1 (see FIG. 6) located on the buffer layer 121, a first gate insulating layer 122 covering the first semiconductor layer SEL1 (see FIG. 6), a first gate conductive layer GCDL1 (see FIG. 6) located on the first gate insulating layer 122, a second gate insulating layer 123 covering the first gate conductive layer GCDL1 (see FIG. 6), a second gate conductive layer GCDL2 (see FIG. 7) located on the second gate insulating layer 123, and a first interlayer insulating layer 124 covering the second gate conductive layer GCDL2 (see FIG. 7).

The circuit layer 120 may include the second semiconductor layer SEL2 (see FIG. 8) located on the first interlayer insulating layer 124, a third gate insulating layer 125 covering the second semiconductor layer SEL2 (see FIG. 8), a third gate conductive layer GCDL3 (see FIG. 8) located on the third gate insulating layer 125, a second interlayer insulating layer 126 covering the third gate conductive layer GCDL3 (see FIG. 8), a first source-drain conductive layer SDCDL1 (see FIG. 9) located on the second interlayer insulating layer 126, a first planarization layer 127 covering the first source-drain conductive layer SDCDL1 (see FIG. 9), a second source-drain conductive layer SDCDL2 (see FIG. 10) located on the first planarization layer 127, and a second planarization layer 128 covering the second source-drain conductive layer SDCDL2 (see FIG. 10).

Referring to FIG. 6, the channel portions CH1, CH2, CH5, CH6, CH7, and CH8, the first electrode portions S1, S2, S5, S6, S7, and S8, and the second electrode portions D1, D2, D5, D6, D7, and D8 of the respective first, second, fifth, sixth, seventh, and eighth transistors T1, T2, T5, T6, T7, and T8 provided as P-type MOSFETs may be located in the first semiconductor layer SEL1 on the buffer layer 121 (see FIG. 13).

At least a part of the channel portion CH1 of the first transistor T1 may overlap the light blocking layer BML.

The first electrode portion S1 of the first transistor T1 may be connected to the second electrode portion D2 of the second transistor T2, the second electrode portion D5 of the fifth transistor T5, and the second electrode portion D8 of the eighth transistor T8.

The second electrode portion D1 of the first transistor T1 may be connected to the first electrode portion S6 of the sixth transistor T6.

The second electrode portion D6 of the sixth transistor T6 may be connected to the second electrode portion D7 of the seventh transistor T7.

A gate electrode GE1 of the first transistor T1 overlapping the channel portion CH1 of the first transistor T1 may be located in the first gate conductive layer GCDL1.

Gate electrodes GE5 and GE6 of the respective fifth and sixth transistors T5 and T6 may be located in the first gate conductive layer GCDL1.

The gate electrode GE5 of the fifth transistor T5 overlaps the channel portion CH5 of the fifth transistor T5.

The gate electrode GE6 of the sixth transistor T6 overlaps the channel portion CH6 of the sixth transistor T6.

The bias control line GBL transmitting the bias control signal GB (see FIG. 5) may be located in the first gate conductive layer GCDL1.

The bias control line GBL may extend in the first direction DR1 and may intersect the channel portion CH7 of the seventh transistor T7 and the channel portion CH8 of the eighth transistor T8.

The gate electrode GE7 of the seventh transistor T7 may be provided as a portion of the bias control line GBL that overlaps the channel portion CH7 of the seventh transistor T7.

The gate electrode GE8 of the eighth transistor T8 may be provided as another portion of the bias control line GBL that overlaps the channel portion CH8 of the eighth transistor T8.

According to some embodiments, the anode initialization voltage line VAIL (see FIG. 5) of the circuit layer 120 may include a first anode initialization voltage line VAIL1 (see FIG. 8) transmitting a first anode initialization voltage for initializing the light emitting element LE of the first emission area EA1 and a second anode initialization voltage VAIL2 (see FIG. 6) transmitting a second anode initialization voltage for initializing the light emitting element LE of the second emission area EA2 and the light emitting element LE of the third emission area EA3.

The second anode initialization voltage line VAIL2 may be located in the first gate conductive layer GCDL1.

According to some embodiments, in the first direction DR1, the width of a part of the light blocking layer BML, which overlaps the channel portion CH1 of the first transistor T1, may be less than the width of the gate electrode GE1 of the first transistor T1.

In this way, in the channel portion CH1 of the first transistor T1 overlapping the gate electrode GE1, a part adjacent to the first electrode portion S1 does not overlap the light blocking layer BML, and thus it may be exposed to light from the substrate 110.

Therefore, because a photocurrent may be induced in the first electrode portion S1 of the first transistor T1 and a part of the channel portion CH1 of the first transistor T1 adjacent thereto, the current characteristics of the first transistor T1 may be enhanced.

As shown in FIG. 7, the circuit layer 120 may include a capacitor electrode CAE located in the second gate conductive layer GCDL2.

The capacitor electrode CAE may overlap the gate electrode GE1 of the first transistor T1.

The first power line VDL transmitting the first power source ELVDD (see FIG. 5) may be located in the second gate conductive layer GCDL2 and extend in the first direction DR1.

The capacitor electrode CAE is connected to the first power line VDL.

That is, the capacitor electrode CAE may be provided as a part of the first power line VDL that overlaps the gate electrode GE1 of the first transistor T1.

Accordingly, the pixel capacitor PC1 (see FIG. 5) may be provided by a region where the capacitor electrode CAE and the gate electrode GE1 of the first transistor T1 overlap each other.

According to some embodiments, the width of the capacitor electrode CAE may be less than the width of the gate electrode GE1 of the first transistor T1 in the first direction DR1.

In this way, because the capacitor electrode CAE does not overlap the first electrode portion S1 of the first transistor T1, light heading from the element layer 130 toward the first electrode portion S1 of the first transistor T1 may not be blocked by the capacitor electrode CAE. That is, the amount of photocurrent induced by light incident from the element layer 130 may be prevented from being reduced by the capacitor electrode CAE. Therefore, the current characteristics of the first transistor T1 may be further enhanced.

According to some embodiments, the circuit layer 120 may further include an additional gate electrode AGE3 of the third transistor T3 (see FIG. 5) and an additional gate electrode AGE4 of the fourth transistor T4 (see FIG. 5) located in the second gate conductive layer GCDL2.

As shown in FIG. 8, the channel portions CH3 and CH4, the first electrode portions S3 and S4, and the second electrodes D3 and D4 of the respective third transistor T3 and fourth transistor T4 provided as N-type MOSFETs may be located in the second semiconductor layer SEL2 on the first interlayer insulating layer 124 (see FIG. 13).

The gate electrodes GE3 and GE4 of the respective third transistor T3 and fourth transistor T4 may be located in the third gate conductive layer GCDL3 on the third gate insulating layer 125 (see FIG. 13) covering the second semiconductor layer SEL2.

The channel portion CH3 of the third transistor T3 may overlap the additional gate electrode AGE3 of the third transistor T3 (see FIG. 5) and the gate electrode GE3 of the third transistor T3.

The first electrode portion S3 of the third transistor T3 may be located adjacent to the second electrode portion D1 of the first transistor T1.

The second electrode portion D3 of the third transistor T3 may be connected to the second electrode portion D4 of the fourth transistor T4.

The channel portion CH4 of the fourth transistor T4 may overlap the additional gate electrode AGE4 of the fourth transistor T4 (see FIG. 5) and the gate electrode GE4 of the fourth transistor T4.

The first anode initialization voltage line VAIL1, which transmits the first anode initialization voltage for initializing the light emitting element LE of the first emission area EA1, may be located in the third gate conductive layer GCDL3 and extend in the first direction DR1.

As shown in FIG. 9, the scan write line GWL transmitting the scan write signal GW (see FIG. 5), the scan initialization line GIL transmitting the scan initialization signal GI (see FIG. 5), the gate control line GCL transmitting the gate control signal GC (see FIG. 5), the emission control line ECL transmitting the emission control signal EC (see FIG. 5), and the bias voltage line VBSL transmitting the bias voltage VBS (see FIG. 5) may be located in the first source-drain conductive layer SDCDL1.

The scan write line GWL may extend in the first direction DR1 and may intersect the gate electrode GE2 (see FIG. 6) of the second transistor T2 (see FIG. 5).

The scan write line GWL may be electrically connected to the gate electrode GE2 (see FIG. 6) of the second transistor T2 (see FIG. 5) through a scan write connection hole GWCH.

The scan initialization line GIL may extend in the first direction DR1 and intersect with the additional gate electrode AGE4 (see FIG. 7) of the fourth transistor T4 (see FIG. 5) and the gate electrode GE4 (see FIG. 8) of the fourth transistor T4.

The scan initialization line GIL may be electrically connected to the additional gate electrode AGE4 (see FIG. 7) of the fourth transistor T4 (see FIG. 5) through a first scan initialization connection hole GICH1, and electrically connected to the gate electrode GE4 (see FIG. 8) of the fourth transistor T4 through a second scan initialization connection hole GICH2.

The gate control line GCL may extend in the first direction DR1 and intersect the additional gate electrode AGE3 (see FIG. 7) of the third transistor T3 (see FIG. 5) and the gate electrode GE3 (see FIG. 8) of the third transistor T3.

The gate control line GCL may be electrically connected to the additional gate electrode AGE3 (see FIG. 7) of the third transistor T3 (see FIG. 5) through a first gate control connection hole GCCH1, and electrically connected to the gate electrode GE3 (see FIG. 8) of the third transistor T3 through a second gate control connection hole GCCH2.

The emission control line ECL may extend in the first direction DR1 and intersect the gate electrode GE5 (see FIG. 6) of the fifth transistor T5 (see FIG. 5) and the gate electrode GE6 (see FIG. 6) of the sixth transistor T6 (see FIG. 5).

The emission control line ECL may be electrically connected to the gate electrode GE5 (see FIG. 6) of the fifth transistor T5 (see FIG. 5) through a first emission control connection hole ECCH1, and electrically connected to the gate electrode GE6 (see FIG. 6) of the sixth transistor T6 (see FIG. 5) through a second emission control connection hole ECCH2.

The bias voltage line VBSL may extend in the first direction DR1 and intersect the first electrode portion S8 (see FIG. 6) of the eighth transistor T8 (see FIG. 5).

The bias voltage line VBSL may be electrically connected to the first electrode portion S8 (see FIG. 6) of the eighth transistor T8 (see FIG. 5) through a bias voltage connection hole VBCH.

The circuit layer 120 may further include a first additional power line VDAL1, a gate connection electrode GCE, a data connection electrode DCE, a node connection electrode NDCE, a first anode connection electrode ANCE1, a first anode initialization connection electrode VAICE1, and a second anode initialization connection electrode VAICE2 located in the first source-drain conductive layer SDCDL1.

The first additional power line VDAL1 may extend in the first direction DR1 and may overlap the first power line VDL (see FIG. 7).

The first additional power line VDAL1 may be electrically connected to the first power line VDL (see FIG. 7) through a first power connection hole VDCH1, and may be electrically connected to the first electrode portion S5 (see FIG. 6) of the fifth transistor T5 (see FIG. 5) through a second power connection hole VDCH2.

In addition, the first additional power line VDAL1 may be electrically connected to the second additional power line VDAL2 (see FIG. 10) through a third power connection hole VDCH3.

The gate connection electrode GCE may be electrically connected to the gate electrode GE1 (see FIG. 6) of the first transistor T1 (see FIG. 5) through a first gate connection hole GCH1, and electrically connected to the second electrode portion D3 (see FIG. 8) of the third transistor T3 (see FIG. 5) and the second electrode portion D4 (see FIG. 8) of the fourth transistor T4 (see FIG. 5) through a second gate connection hole GCH2.

The data connection electrode DCE may be electrically connected to the first electrode portion S2 (see FIG. 6) of the second transistor T2 (see FIG. 5) through the data additional connection hole DACH.

The node connection electrode NDCE may be electrically connected to the second electrode portion D1 (see FIG. 6) of the first transistor T1 (see FIG. 5) through a first node connection hole NDCH1, and electrically connected to the first electrode portion S3 (see FIG. 8) of the third transistor T3 (see FIG. 5) through a second node connection hole NDCH2.

The first anode connection electrode ANCE1 may be electrically connected to the second electrode portion D6 of the sixth transistor T6 (see FIG. 5) and the second electrode portion D7 (see FIG. 6) of the seventh transistor T7 (see FIG. 5) through the first anode connection hole ANCH1.

The first anode initialization connection electrode VAICE1 may be electrically connected to the first electrode portion S7 (see FIG. 6) of the seventh transistor T7 (see FIG. 5) of the first light emitting pixel driver EPD1 through a first anode initialization connection hole VAICH1, and electrically connected to the first anode initialization voltage line VAIL1 (see FIG. 8) through a second anode initialization connection hole VAICH2.

The second anode initialization connection electrode VAICE2 may be electrically connected to the first electrode portion S7 (see FIG. 6) of the seventh transistor T7 (see FIG. 5) of the second light emitting pixel driver EPD2 or the third light emitting pixel driver EPD3 through a third anode initialization connection hole VAICH3, and electrically connected the second anode initialization voltage line VAIL2 (see FIG. 6) through a fourth anode initialization connection hole VAICH4.

Referring to FIG. 10, the data line DL transmitting the data signal Vdata (see FIG. 5) may extend in the second direction DR2 and may be located in the second source-drain conductive layer SDCDL2.

The data line DL may be electrically connected to the data connection electrode DCE (see FIG. 9) through a data connection hole DTCH (see FIG. 9).

The circuit layer 120 may further include a dummy data line DDL, a second additional power line VDAL2, and a second anode connection electrode ANCE2 located in the second source-drain conductive layer SDCDL2.

The dummy data line DDL may overlap the third light emitting pixel driver EPD3 and may be symmetrical with the adjacent data line DL.

The dummy data line DDL is not for transmitting the data signal Vdata (see FIG. 5), but for reducing the visibility of the data line DL.

The second additional power line VDAL2 may extend in the second direction DR2 and may overlap the boundary between the first light emitting pixel driver EPD1 and the second light emitting pixel driver EPD2, or the third light emitting pixel driver EPD3.

The second additional power line VDAL2 may be electrically connected to the first additional power line VDAL1 (see FIG. 9) through the third power connection hole VDCH3 (see FIG. 9).

The second anode connection electrode ANCE2 may be electrically connected to the first anode connection electrode ANCE1 (see FIG. 9) through a second anode connection hole ANCH2.

As shown in FIG. 13, the element layer 130 may be located on the second planarization layer 128 covering the second source-drain conductive layer SDCDL2 (see FIG. 10).

According to some embodiments, the element layer 130 may include anode electrodes 131 located in the emission areas EA (see FIG. 4) on the circuit layer 120, and a pixel defining layer 132 located on the circuit layer 120 and containing a light absorbing material that absorbs light.

The pixel defining layer 132 may include anode openings ANOP overlapping the anode electrodes 131 and a light transmitting opening LTOP overlapping a part of the first transistor T1 (i.e., at least a part of the first electrode portion S1).

The anode openings ANOP may be located in the emission areas EA (see FIG. 4).

The light transmitting opening LTOP may be located in a non-emission area NEA (see FIG. 4) and spaced apart from the anode openings ANOP and the anode electrodes 131.

Accordingly, the pixel defining layer 132 may cover the edges of the anode electrodes 131. That is, the edges of the anode electrodes 131 are covered with the pixel defining layer 132 so that they are not in contact with the light emitting layer 133. Therefore, carriers of the light emitting layer 133 may be prevented from being concentrated in the edges of the anode electrodes 131.

The element layer 130 may further include the light emitting layers 133 located above the anode electrodes 131 and a cathode electrode 134 located above the pixel defining layer 132 and the light emitting layers 133 in the anode openings ANOP.

Further, the element layer 130 may further include first common layers 135 located between the anode electrodes 131 and the light emitting layers 133, and a second common layer 136 located between the light emitting layers 133 and the cathode electrode 134.

The encapsulation layer 140 may include a first encapsulation layer 141 located on the element layer 130 and made of an inorganic insulating material, a second encapsulation layer 142 located on the first encapsulation layer 141, overlapping the element layer 130, and made of an organic insulating material, and a third encapsulation layer 143 covering the second encapsulation layer 142 and made of an inorganic insulating material.

According to some embodiments, the light transmitting opening LTOP located in the non-emission area NEA (see FIG. 4) may overlap at least a part of the first electrode portion S1 of the first transistor T1.

Because the pixel defining layer 132 having the light absorbing material is removed by the light transmitting opening LTOP, light may be incident from the element layer 130 to the circuit layer 120 through the light transmitting opening LTOP. Accordingly, the first electrode portion S1 of the first transistor T1 may be exposed to light incident through the light transmitting opening LTOP, and thus the current characteristics of the first transistor T1 may be enhanced.

Therefore, the luminance of the light emitting element LE may be enhanced, thereby improving the display quality of the display device 100 and the electronic device including the same.

As shown in FIG. 11, an anode electrode 1311 of the first emission area EA1 (see FIG. 4) may be electrically connected to the second anode connection electrode ANCE2 of the first light emitting pixel driver EPD1.

An anode electrode 1312 of the second emission area EA2 (see FIG. 4) may be electrically connected to the second anode connection electrode ANCE2 of the second light emitting pixel driver EPD2.

An anode electrode 1313 of the third emission area EA3 (see FIG. 4) may be electrically connected to the second anode connection electrode ANCE2 of the third light emitting pixel driver EPD3.

In each of the emission areas EA, the anode opening ANOP may overlap a part of the center of the anode electrode 131.

The light transmitting opening LTOP may be spaced apart from the anode electrodes 131 and the anode openings ANOP.

As shown in FIGS. 11 and 12, the light transmitting opening LTOP may be located between the anode opening ANOP of the second emission area EA2 (see FIG. 4) and the anode opening ANOP of the third emission area EA3 (see FIG. 4) in the first direction DR1.

As shown in FIG. 12, the light transmitting opening LTOP may overlap at least a part of the first electrode portion S1 of the first transistor T1.

That is, the light transmitting opening LTOP may be located adjacent to the gate electrode GE1 and the first electrode portion S1 of the first transistor T1.

For example, the light transmitting opening LTOP may overlap a part of the first electrode portion S1 of the first transistor T1, which is adjacent to the channel portion CH1 (see FIG. 6) of the first transistor T1.

In this way, light incident through the light transmitting opening LTOP may be easily transmitted to the channel portion CH1 (see FIG. 6) of the first transistor T1 through the buffer layer 121 (see FIG. 13), the first gate insulating layer 122 (see FIG. 13), and the like. Therefore, a photocurrent may also be induced in the channel portion CH1 (see FIG. 6) of the first transistor T1, and thus the current characteristics of the first transistor T1 may be further enhanced.

A part of the light blocking layer BML overlapping the gate electrode GE1 of the first transistor T1 may be spaced apart from the light transmitting opening LTOP.

To this end, in the first direction DR1, in which the gate electrode GE1 of the first transistor T1 and the light transmitting opening LTOP face each other, the width of the part of the light blocking layer BML overlapping the gate electrode GE1 of the first transistor T1 may be less than that of the gate electrode GE1 of the first transistor T1.

That is, the gate electrode GE1 of the first transistor T1 may protrude toward the light transmitting opening LTOP than the light blocking layer BML in the first direction DR1.

In this way, a part of the channel portion CH1 (see FIG. 6) of the first transistor T1 may be exposed to light incident from the substrate 110, and thus the current characteristics of the first transistor T1 may be further enhanced.

According to some embodiments, the capacitor electrode CAE may be spaced apart from the light transmitting opening LTOP.

To this end, in the first direction DR1, in which the gate electrode GE1 of the first transistor T1 and the light transmitting opening LTOP face each other, the width of the capacitor electrode CAE may be less than the width of the gate electrode GE1 of the first transistor T1.

That is, the gate electrode GE1 of the first transistor T1 may protrude toward the light transmitting opening LTOP than the capacitor electrode CAE in the first direction DR1.

In this way, light incident on the part of the first electrode portion S1 of the first transistor T1, which is adjacent to the channel portion CH1 (see FIG. 6) of the first transistor T1, may not be blocked by the capacitor electrode CAE, so that the current characteristics of the first transistor T1 may be further enhanced.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a substrate comprising emission areas;
a circuit layer on the substrate; and
an element layer on the circuit layer and comprising light emitting elements in the emission areas,
wherein the circuit layer comprises light emitting pixel drivers electrically connected to the light emitting elements,
each of the light emitting pixel drivers comprises a first transistor electrically connected between a first node and a second node,
the element layer comprises:
anode electrodes in the emission areas on the circuit layer; and
a pixel defining layer on the circuit layer and containing a light absorbing material configured to absorb light, and
the pixel defining layer comprises:
anode openings overlapping the anode electrodes; and
a light transmitting opening overlapping a part of the first transistor.

2. The display device of claim 1, wherein the pixel defining layer covers edges of the anode electrodes,
the light transmitting opening is spaced apart from the anode openings and the anode electrodes,
the element layer further comprises:
light emitting layers on the anode electrodes through the anode openings; and
a cathode electrode on the pixel defining layer and the light emitting layers, and
each of the light emitting elements has a structure in which the light emitting layer is interposed between the anode electrode and the cathode electrode facing each other.

3. The display device of claim 2, wherein the light emitting pixel drivers further comprise a second transistor electrically connected between a data line configured to transmit a data signal and the first node,
the circuit layer comprises:
a light blocking layer on the substrate;
a buffer layer covering the light blocking layer;
a first semiconductor layer on the buffer layer;
a first gate insulating layer covering the first semiconductor layer;
a first gate conductive layer on the first gate insulating layer;
a second gate insulating layer covering the first gate conductive layer;
a second gate conductive layer on the second gate insulating layer; and
a first interlayer insulating layer covering the second gate conductive layer,
a channel portion, a first electrode portion and a second electrode portion of each of the first transistor and the second transistor are in the first semiconductor layer, and
a gate electrode of each of the first transistor and the second transistor is in the first gate conductive layer.

4. The display device of claim 3, wherein in the first semiconductor layer, the channel portion of the first transistor overlaps the gate electrode of the first transistor,
in the first semiconductor layer, the first electrode portion of the first transistor is connected to a first side of the channel portion of the first transistor and the second electrode portion of the second transistor,
in the first semiconductor layer, the second electrode portion of the first transistor is connected to a second side of the channel portion of the first transistor, and
the light transmitting opening overlaps at least a part of the first electrode portion of the first transistor in the first semiconductor layer.

5. The display device of claim 4, wherein the light transmitting opening is adjacent to the gate electrode and the channel portion of the first transistor.

6. The display device of claim 5, wherein a part of the light blocking layer, which overlaps the gate electrode of the first transistor, is spaced apart from the light transmitting opening.

7. The display device of claim 5, wherein in a direction in which the gate electrode of the first transistor and the light transmitting opening face each other, a width of a part of the light blocking layer is less than a width of the gate electrode of the first transistor.

8. The display device of claim 3, wherein the gate electrode of the first transistor is electrically connected to a third node,
the light emitting elements are electrically connected to a fourth node of the light emitting pixel drivers, and
the light emitting pixel drivers further comprise:
a pixel capacitor electrically connected between a first power line configured to transmit a first power source and the third node;
a third transistor electrically connected between the second node and the third node;
a fourth transistor electrically connected between a gate initialization voltage line configured to transmit a gate initialization voltage and the third node;
a fifth transistor electrically connected between the first power line and the first node;
a sixth transistor electrically connected between the second node and the fourth node;
a seventh transistor electrically connected between an anode initialization voltage line configured to transmit an anode initialization voltage and the fourth node; and
an eighth transistor electrically connected between a bias voltage line configured to transmit a bias voltage and the first node,
wherein a channel portion, a first electrode portion and a second electrode portion of each of the fifth transistor, the sixth transistor, the seventh transistor, and the eighth transistor are in the first semiconductor layer, and
a gate electrode of each of the fifth transistor, the sixth transistor, the seventh transistor, and the eighth transistor is in the first gate conductive layer.

9. The display device of claim 8, wherein the circuit layer further comprises a capacitor electrode in the second gate conductive layer and overlapping the gate electrode of the first transistor,
the pixel capacitor is provided by a region where the capacitor electrode and the gate electrode of the first transistor overlap each other, and
the light transmitting opening is spaced apart from the capacitor electrode.

10. The display device of claim 9, wherein in a direction in which the gate electrode of the first transistor and the light emitting opening face each other, a width of the capacitor electrode is less than a width of the gate electrode of the first transistor.

11. The display device of claim 8, wherein the circuit layer further comprises:
a second semiconductor layer on the first interlayer insulating layer;
a third gate insulating layer covering the second semiconductor layer;
a third gate conductive layer on the third gate insulating layer;
a second interlayer insulating layer covering the third gate conductive layer;
a first source-drain conductive layer on the second interlayer insulating layer;
a first planarization layer covering the first source-drain conductive layer;
a second source-drain conductive layer on the first planarization layer; and
a second planarization layer covering the second source-drain conductive layer,
wherein a channel portion, a first electrode portion and a second electrode portion of each of the third transistor and the fourth transistor are in the second semiconductor layer,
a gate electrode of each of the third transistor and the fourth transistor is in the third gate conductive layer,
an additional gate electrode of each of the third transistor and the fourth transistor is in the second gate conductive layer, and
at least a part of the first electrode portion of the first transistor in the first semiconductor layer overlaps the light transmitting opening, and is spaced apart from the third gate conductive layer, the first source-drain conductive layer, and the second source-drain conductive layer.

12. An electronic device comprising a display device providing a screen,
wherein the display device comprises:
a substrate comprising emission areas;
a circuit layer on the substrate; and
an element layer on the circuit layer and comprising light emitting elements in the emission areas,
wherein the circuit layer comprises light emitting pixel drivers electrically connected to the light emitting elements,
each of the light emitting pixel drivers comprises a first transistor electrically connected between a first node and a second node,
the element layer comprises:
anode electrodes in the emission areas on the circuit layer; and
a pixel defining layer on the circuit layer and containing a light absorbing material configured to absorb light, and
the pixel defining layer comprises:
anode openings overlapping the anode electrodes; and
a light transmitting opening overlapping a part of the first transistor.

13. The electronic device of claim 12, wherein the pixel defining layer covers edges of the anode electrodes,
the light transmitting opening is spaced apart from the anode openings and the anode electrodes,
the element layer further comprises:
light emitting layers on the anode electrodes through the anode openings; and
a cathode electrode on the pixel defining layer and the light emitting layers, and
each of the light emitting elements has a structure in which the light emitting layer is interposed between the anode electrode and the cathode electrode facing each other.

14. The electronic device of claim 13, wherein the circuit layer comprises:
a light blocking layer on the substrate;
a buffer layer covering the light blocking layer;
a first semiconductor layer on the buffer layer;
a first gate insulating layer covering the first semiconductor layer;
a first gate conductive layer on the first gate insulating layer;
a second gate insulating layer covering the first gate conductive layer;
a second gate conductive layer on the second gate insulating layer; and
a first interlayer insulating layer covering the second gate conductive layer,
a second semiconductor layer on the first interlayer insulating layer;
a third gate insulating layer covering the second semiconductor layer;
a third gate conductive layer on the third gate insulating layer;
a second interlayer insulating layer covering the third gate conductive layer;
a first source-drain conductive layer on the second interlayer insulating layer;
a first planarization layer covering the first source-drain conductive layer;
a second source-drain conductive layer on the first planarization layer; and
a second planarization layer covering the second source-drain conductive layer,
a channel portion, a first electrode portion and a second electrode portion of each of the first transistor and a second transistor are in the first semiconductor layer,
a gate electrode of each of the first transistor and the second transistor is in the first gate conductive layer,
in the first semiconductor layer, the channel portion of the first transistor overlaps the gate electrode of the first transistor,
in the first semiconductor layer, the first electrode portion of the first transistor is connected to a first side of the channel portion of the first transistor and the second electrode portion of the second transistor,
in the first semiconductor layer, the second electrode portion of the first transistor is connected to a second side of the channel portion of the first transistor, and
the light transmitting opening overlaps at least a part of the first electrode portion of the first transistor in the first semiconductor layer.

15. The electronic device of claim 14, wherein at least a part of the first electrode portion of the first transistor in the first semiconductor layer overlaps the light transmitting opening, and is spaced apart from the third gate conductive layer, the first source-drain conductive layer, and the second source-drain conductive layer.

16. The electronic device of claim 14, wherein the light transmitting opening is adjacent to the gate electrode and the channel portion of the first transistor, and
a part of the light blocking layer, which overlaps the gate electrode of the first transistor, is spaced apart from the light transmitting opening.

17. The electronic device of claim 16, wherein in a direction in which the gate electrode of the first transistor and the light transmitting opening face each other, a width of a part of the light blocking layer is less than a width of the gate electrode of the first transistor.

18. The electronic device of claim 14, wherein the gate electrode of the first transistor is electrically connected to a third node,
the light emitting elements are electrically connected to a fourth node of the light emitting pixel drivers, and
the light emitting pixel drivers further comprise:
a second transistor electrically connected between a data line configured to transmit a data signal and the first node;
a pixel capacitor electrically connected between a first power line configured to transmit a first power source and the third node;
a third transistor electrically connected between the second node and the third node;
a fourth transistor electrically connected between a gate initialization voltage line configured to transmit a gate initialization voltage and the third node;
a fifth transistor electrically connected between the first power line and the first node;
a sixth transistor electrically connected between the second node and the fourth node;
a seventh transistor electrically connected between an anode initialization voltage line configured to transmit an anode initialization voltage and the fourth node; and
an eighth transistor electrically connected between a bias voltage line configured to transmit a bias voltage and the first node,
wherein a channel portion, a first electrode portion and a second electrode portion of each of the second transistor, the fifth transistor, the sixth transistor, the seventh transistor, and the eighth transistor are in the first semiconductor layer,
a gate electrode of each of the second transistor, the fifth transistor, the sixth transistor, the seventh transistor, and the eighth transistor is in the first gate conductive layer,
a channel portion, a first electrode portion and a second electrode portion of each of the third transistor and the fourth transistor are in the second semiconductor layer,
a gate electrode of each of the third transistor and the fourth transistor is in the third gate conductive layer, and
an additional gate electrode of each of the third transistor and the fourth transistor is in the second gate conductive layer.

19. The electronic device of claim 18, wherein the circuit layer further comprises a capacitor electrode in the second gate conductive layer and overlapping the gate electrode of the first transistor,
the pixel capacitor is provided by a region where the capacitor electrode and the gate electrode of the first transistor overlap each other, and
the light transmitting opening is spaced apart from the capacitor electrode.

20. The electronic device of claim 19, wherein in a direction in which the gate electrode of the first transistor and the light emitting opening face each other, a width of the capacitor electrode is less than a width of the gate electrode of the first transistor.
